(19) United States
(12) Patent Application Publication
(10) Pub. No.: US 2023/0222394 A1
(43) Pub. Date: Jul. 13, 2023

(54) PREDICTIVE MODELING FOR CHAMBER CONDITION MONITORING

(71) Applicant: Applied Materials, Inc., Santa Clara, CA (US)

(72) Inventors: Jeong Jin Hong, Yongin (KR); Sejune Cheon, Seoul (KR)

(21) Appl. No.: 17/571,320

(22) Filed: Jan. 7, 2022

(51) Int. Cl. G06N 20/20; G06K 9/62; H01L 21/66

(52) U.S. Cl. CPC G06N 20/20; G06K 9/6247; G06K 9/6256; H01L 22/12

(57) ABSTRACT

The subject matter of this specification can be implemented in, among other things, methods, systems, computer-readable storage medium. A method can include a processing device receiving training data. The training data may include first sensor data indicating a first state of an environment of a first processing chamber processing a first substrate. The training data may further include first process tool data indicating a state of first processing tools processing the first substrate. The training data may further include first process result data corresponding to the first substrate processed by the first process tool. The processing device may further train a first model using the training data. The trained first model receives new input having second sensor data and second process tool data to produce second output based on the new input. The second output indicating a second process result data corresponding to a second substrate.

### TECHNICAL FIELD

Embodiments of the instant specification generally relates to predictive modeling for chamber condition monitoring. More specifically, the embodiments of the instant specification relates to multi-input, multi-output (MIMO) modeling for chamber condition prediction and monitoring.

### BACKGROUND

Many industries employ sophisticated manufacturing equipment that includes multiple sensors and controls, each of which may be carefully monitored during processing to ensure product quality. One method of monitoring the multiple sensors and controls is statistical process monitoring (a means of performing statistical analysis on sensor measurements and process control values (process variables)), which enables automatic detection and/or diagnosis of “faults.” A “fault” can be a malfunction or maladjustment of manufacturing equipment (e.g., deviation of a machine’s operating parameters from intended values), or an indication of a need for preventive maintenance to prevent an imminent malfunction or maladjustment. Faults can produce defects in the devices being manufactured. Accordingly, one goal of statistical process monitoring is to detect and/or diagnose faults before they produce such defects.

During process monitoring, a fault is detected when one or more of the statistics of recent process data deviate from a statistical model by an amount great enough to cause a model metric to exceed a respective confidence threshold. A model metric is a scalar number whose value represents a magnitude of deviation between the statistical characteristics of process data collected during actual process monitoring and the statistical characteristics predicted by the model. Each model metric is a unique mathematical method of estimating this deviation. Each model metric has a respective confidence threshold, also referred to as a confidence limit or control limit, whose value represents an acceptable upper or lower limit of the model metric. If a model metric exceeds its respective confidence threshold during process monitoring, it can be inferred that the process data has aberrant statistics because of a fault.

An obstacle to accurate fault detection is the fact that manufacturing processes commonly drift over time, even in the absence of any problems. For example, the operating conditions within a semiconductor process chamber typically drift between successive cleanings of the chamber and between successive replacements of consumable chamber components. Conventional statistical process monitoring methods for fault detection suffer shortcomings in distinguishing normal drift from a fault. Specifically, some fault detection methods employ a static model, which assumes that process conditions remain constant over the life of a tool. Such a model does not distinguish between expected changes over time and unexpected deviations caused by a fault. To prevent process drift from triggering numerous false alarms, the control limit must be set wide enough to accommodate drift. Consequently, the model may fail to detect subtle faults.

### SUMMARY

A method, system, and computer readable media (CRM) for chamber condition prediction and monitoring. In some embodiments, a method, performed by a processing device, may include, receiving training including first sensor data indicating a first state of an environment of a first processing chamber processing a first substrate. The training data may further include first process tool data indicating a time-dependent state of the first processing tools processing the first substrate. The training data may further include first process result data corresponding to the first substrate. The processing device may further train a first model with input data that includes the first sensor data and the first process tool data and target output that includes the process result data. The trained first model may receive a new input having second sensor data indicating a second state of an environment of a second processing tool processing the second substrate and second process tool data indicating a second time-dependent state of a second processing tool processing the second substrate to produce a second output based on the new input. The second output indicating a second process result data may correspond to the second substrate.

In some embodiments, a method may include a processing device receiving sensor data indicating a state of an environment of a processing chamber processing a first substrate according to a substrate processing process. The processing device may receive process tool data indicating a relative operation life of a processing tool processing the first substrate relative to other process tools of a selection of process tools. The method includes processing the sensor data and the process tool data using one or more machine-learning models (MLMs) to determine a prediction of a process result measurement of the first substrate. The processing may further prepare the prediction for presentation on a graphical user interface (GUI). The processing device may further alter an operation of at least one of the process chamber of the processing tool based on the prediction.

In some embodiments, a method includes training a machine learning model (MLM). Training the MLM may include receiving training data that includes first sensor data indicating a first state of an environment of a first process chamber processing a first substrate. The training data further includes metrology data including process result measurements and location data indicating first locations across a surface of the substrate corresponding to the process result measurements. Training the MLM may further include encoding the training data to generate encoded training data. Training the MLM may further include causing a regression to be performed using the encoded training data. The method may further include receiving second sensor data indicating a second state of an environment of a second process chamber processing a second substrate. The method may further include encoding the sensor data to generate encoded sensor data. The method may further include using the encoded sensor data as input to the trained MLM and receiving one or more outputs from the trained MLM. The one or more outputs may include encoded prediction data. The method may further include decoding the encoded prediction data to generate prediction data that includes value indicating process results of the second substrate in second locations across a surface of the second substrate, the second locations corresponding to the first locations of the first substrate.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a block diagram illustrating an example system architecture in which implementations of the disclosure may operate.

FIG. 2 is a block diagram illustrating a process result prediction system in which implementations of the disclosure may operate.

FIG. 3A depicts a graph illustrating process result data, in accordance with some implementations of the present disclosure.

FIG. 3B depicts a graph illustrating process result data after data pre-process logic, in accordance with some implementations of the present disclosure.

FIG. 4 is a block diagram illustrating a process result prediction system in which implementations of the disclosure may operate.

FIG. 5A is an example data set generator to create data sets for a machine learning model (e.g., one or of the MLMs described herein) using substrate processing data), according to certain embodiments.

FIG. 5B is a block diagram illustrating a system for training a machine learning model to generate outputs, according to certain embodiments.

FIG. 6 illustrates block diagram of a process result prediction system using stacked modeling, according to aspects of the disclosure.

FIG. 7 illustrates a model training workflow and a model application workflow for substrate process result prediction, according to aspects of the disclosure.

FIG. 8 depicts a flow diagram of one example method for predicting a process results of a substrate process, in accordance with some implementations of the present disclosure.

FIG. 9 depicts a flow diagram of one example method for monitoring and predicting a process results, in accordance with some implementations of the present disclosure.

FIG. 10 depicts a block diagram of an example computing device, operating in accordance with one or more aspects of the present disclosure.

### DETAILED DESCRIPTION

Substrate processing may include a series of processes that produces electrical circuits in a substrate, a semiconductor, a silicon wafer, etc., in accordance with a circuit design. These processes may be carried out in a series of chambers. Successful operation of a modern semiconductor fabrication facility may aim to facilitate a steady stream of substrate (e.g., wafers) to be moved from one chamber to another in the course of forming electrical circuits in the substrate. In the process of performing many substrate procedures, conditions of processing chambers and processing may adjust over time (e.g., depreciate) and result in processed substrates failing to meet desired conditions or process results (e.g., critical dimensions, process uniformity, thickness dimensions, etc.). Drift in film properties is a cause of concern as it affects the device performance and yield. Metrology (such as those of wafers) may incur additional cost of using a metrology tool, measurement time, and an added risk that additional defects may be added to the substrate. Corrective action may be taken as a result of the metrology, however, there is a delay in awaiting metrology results and performing metrology on a high volume of substrate (e.g., every wafer) can be costly.

Critical dimension (CD) measurement is an important step for substrate processing such as etching. However due to various rationale such as throughput requirements, it has a very low measurement sampling rate among conventional systems. Therefore, using CD measured values to monitor whether a substrate process is in good condition is very difficult in high volume manufacturing. To challenge this difficulty many types of prediction model have being developed, as will be discussed herein. Prediction models can produce predicted CD values for all substrate and can be utilized to detect abnormal CD changes before the measurement is completed by conventional metrology systems. The disclosed predictions models can further be integrated with a tool to tool matching (TTTM) process and can detect abnormal conditions with greater efficiency conduct corrective actions faster (e.g., improving “green to green” time).

Conventional prediction modeling algorithms do not take any physical meaning or any process knowledge into account for model building. Conventional model often only consider correlation patterns between input and output in a statistical manner which can prove difficult to extract proper relationships without knowing how a process is carried out, especially in semiconductor processes. For example, prediction models based on conventional regression approaches do not meet threshold accuracy criteria often because conventional prediction models do not account for spatial correlations across a substrate.

Aspects and implementations of the present disclosure address these and other shortcomings of existing technology by providing methods and systems in various embodiments capable of predicting qualities of substrates (e.g., process results) based on process parameters (e.g., chamber conditions, process tool conditions, etc.). A new ensemble modeling approach is proposed (e.g., to tackle the above-mentioned limitations). Firstly, the output values in the models’ training data are pre-processed to remove time-dependent variations. Such behaviors arise from changes due to different chamber conditions which in turn are due to chamber lifetime differences in manufacturing equipment. Secondly, a boosting technique is applied to improve prediction performance. Since CD profiles from different chambers are often nonlinear, boosting can extract useful relationship information. Thirdly, a spatial function is developed and is integrated with a regression model to train a model to leverage process patterns across locations of the processed substrates.

In an example embodiment, a method, system, and computer readable media (CRM) for chamber condition prediction and monitoring are provided. In some embodiments, a method, performed by a processing device, may include, receiving training including first sensor data indicating a first state of an environment of a first processing chamber processing a first substrate. The training data may further include first process tool data indicating a time-dependent state of the first processing tools processing the first substrate. The training data may further include first process result data corresponding to the first substrate. The processing device may further train a first model with input data that includes the first sensor data and the first process tool data and target output that includes the process result data. The trained first model may receive a new input having second sensor data indicating a second state of an environment of a second processing tool processing the second substrate and second process tool data indicating a second time-dependent state of a second processing tool processing the second substrate to produce a second output based on the new input. The second output indicating a second process result data may correspond to the second substrate.

In an example embodiment, a method may include a processing device receiving sensor data indicating a state of an environment of a processing chamber processing a first substrate according to a substrate processing process. The processing device may receive process tool data indicating a relative operation life of a processing tool processing the first substrate relative to other process tools of a selection of process tools. The method includes processing the sensor data and the process tool data using one or more machine-learning models (MLMs) to determine a prediction of a process result measurement of the first substrate. The processing may further prepare the prediction for presentation on a graphical user interface (GUI). The processing device may further alter an operation of at least one of the process chamber of the processing tool based on the prediction.

In an example embodiment, a method includes training a machine learning model (MLM). Training the MLM may include receiving training data that includes first sensor data indicating a first state of an environment of a first process chamber processing a first substrate. The training data further includes metrology data including process result measurements and location data indicating first locations across a surface of the substrate corresponding to the process result measurements. Training the MLM may further include encoding the training data to generate encoded training data. Training the MLM may further include causing a regression to be performed using the encoded training data. The method may further include receiving second sensor data indicating a second state of an environment of a second process chamber processing a second substrate. The method may further include encoding the sensor data to generate encoded sensor data. The method may further include using the encoded sensor data as input to the trained MLM and receiving one or more outputs from the trained MLM. The one or more outputs may include encoded prediction data. The method may further include decoding the encoded prediction data to generate prediction data that includes value indicating process results of the second substrate in second locations across a surface of the second substrate, the second locations corresponding to the first locations of the first substrate.

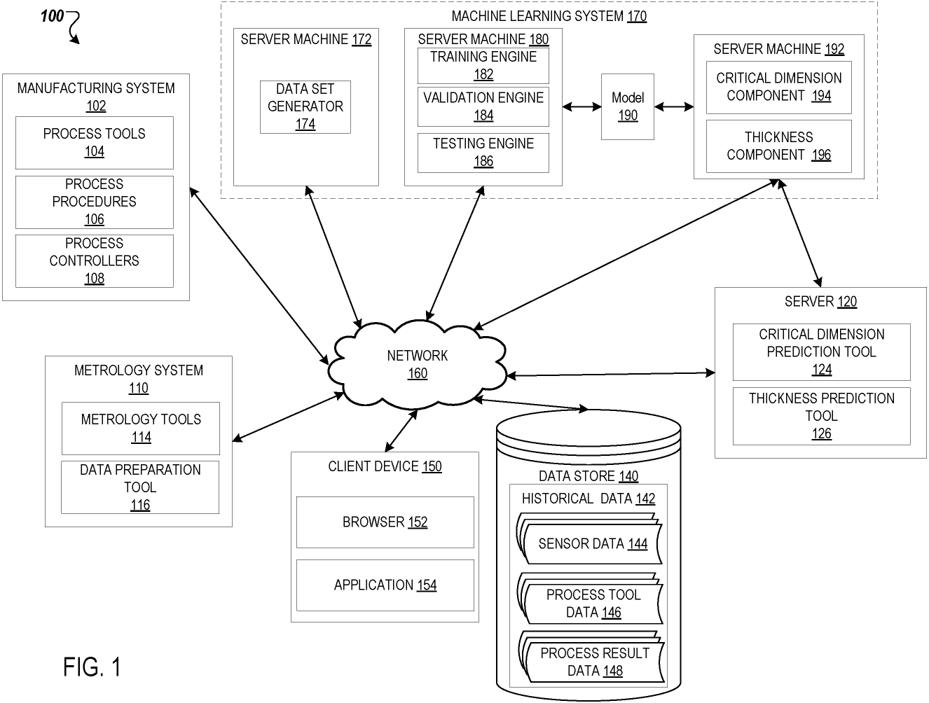

FIG. 1 is a block diagram illustrating an example system architecture 100 in which implementations of the disclosure may operate. As shown in FIG. 1, system architecture 100 includes a manufacturing system 102, a metrology system 110, a client device 150, a data store 140, a server 120, and a machine learning system 170. The machine learning system 170 may be part of the server 120. In some embodiments, one or more components of the machine learning system 170 may be fully or partially integrated into client device 150. The manufacturing system 102, the metrology system 110, the client device 150, the data store 140, the server 120, and the machine learning system 170 can each be hosted by one or more computing devices including server computers, desktop computers, laptop computers, tablet computers, notebook computers, personal digital assistants (PDAs), mobile communication devices, cell phones, hand-held computers, cloud servers, cloud-based system (e.g. cloud service device, cloud network device, or similar computing devices.

The manufacturing system 102, the metrology system 110, client device 150, data store 140, server 120, and machine learning system 170 may be coupled to each other via a network 160 (e.g., for performing methodology described herein). In some embodiments, network 160 is a private network that provides each element of system architecture 100 with access to each other and other privately available computing devices. Network 160 may include one or more wide area networks (WANs), local area networks (LANs), wired network (e.g., Ethernet network), wireless networks (e.g., an 802.11 network or a Wi-Fi network), cellular network (e.g., a Long Term Evolution (LTE) network), routers, hubs, switches, server computers, and/or any combination thereof. In some embodiments, network 160 is a cloud-based network capable of performing cloud-based functionality (e.g., providing cloud service functionality to one or more device in the system) Alternatively or additionally, any of the elements of the system architecture 100 can be integrated together or otherwise coupled without the use of network 160.

The client device 150 may be or include any personal computers (PCs), laptops, mobile phones, tablet computers, netbook computers, network connected televisions (“smart TV”), network-connected media players (e.g., Blue-ray player), a set-top-box, over-the-top (OOT) streaming devices, operator boxes, etc.. The client device may be capable of performing cloud based operations (e.g., with server 120, data store 140, manufacturing system 102, machine learning system 170, metrology system 110, etc.) The client device 150 may include a browser 152, an application 154, and/or other tools as described and performed by other systems of the system architecture 100. In some embodiments, the client device 150 may be capable of accessing the manufacturing system 102, the metrology system 110, the data store 140, server 120, and/or machine learning system 170 and communicating (e.g., transmitting and/or receiving) indications of sensor data, processed data, data classifications (e.g., process result predictions), process result data (e.g., critical dimension data, thickness data), and/or inputs and outputs of various process tools (e.g., metrology tool 114, data preparation tool 116, critical dimension prediction tool 124, thickness prediction tool 126, critical dimension component 194, and/or thickness component 196) at various stages processing of the system architecture 100, as described herein.

As shown in FIG. 1, manufacturing system 102 includes process tools 104, process procedures 106, and process controllers 108. A process controller 108 may coordinate operation of process tools 104 to perform on one or more process procedure 106. For example, various process tools may include specialized chambers such as etch chambers, deposition chambers (including chambers for atomic layer deposition, chemical vapor deposition, sputtering chamber, physical vapor deposition, or plasma enhanced versions thereof), anneal chambers, implant chambers, plating chambers, treatment chambers, and/or the like. In another example, machines may incorporate sample transportation systems (e.g., a selective compliance assembly robot arm (SCARA) robot, transfer chambers, front opening pods (FOUPs), side storage pod (SSP), and/or the like) to transport a sample between machines and process steps.

Process procedures 106 or sometimes referred to as process recipes or process steps may include various specifications for carrying out operations by the process tools 104. For example, a process procedure 106 may include process specifications such as duration of activation of a process operation, the process tool used for the operation, the temperature, flow, pressure, etc. of a machine (e.g., a chamber), order of deposition, and the like. In another example, process procedures may include transferring instructions for transporting a sample to a further process step or to be measured by metrology system 110.

Process controllers 108 can include devices designed to manage and coordinate the actions of process tools 104. In some embodiments, process controllers 108 are associated with a process recipe or series of process procedures 106 instructions that when applied in a designed manner result in a desired process result of a substrate process. For example, a process recipe may be associated with processing a substrate to produce a target process results (e.g., critical dimension, thickness, uniformity criteria, etc.)

As shown in FIG. 1, metrology system 110 includes metrology tools 114 and data preparation tool 116. Metrology tools 114 can include a variety of sensors to measure process results (e.g., critical dimension, thickness, uniformity, etc.) within the manufacturing system 102. For example, wafers processed within one or more processing chamber can be used to measure a critical dimension. Metrology tools 114 may also include devices to measure process results of substrate processed using the manufacturing system. For example, process results such as critical dimensions, thickness measurements (e.g., film layers from etches, depositing, etc.) can be evaluated of substrates processed according to process recipe and/or action performed by process controllers 108. Those measurement can also be used to measure conditions of a chamber throughout a substrate process procedure.

Data preparation tool 116 may include process methodology to extract features and/or generate synthetic/engineered data associated with data measured by metrology tools 114. In some embodiments, data preparation tool 116 can identify correlations, patterns, and/or abnormalities of metrology or process performance data. For example, data preparation tool 116 may perform a feature extraction where data preparation tool 116 uses combinations of measured data to determine whether a criterion is satisfied. For example, data preparation tool 116 can analyze multiple data points of an associated parameter (e.g., thickness, critical dimension, defectivity, plasma condition, etc.) to determine whether rapid changes occurred during a substrate process procedure across multiple processing chambers. In some embodiments, data preparation tool 116 performing a normalization across the various sensor data associated with various process chamber conditions. A normalization may include processing the incoming sensor data to appear similar across the various chambers and sensors used to acquire the data.

In some embodiments, data preparation tool 116 can perform one or more of a process control analysis, univariate limit violation analysis, or a multivariate limit violation analysis on metrology data (e.g., obtained by metrology tools 114). For example, data preparation tool 116 can perform statistical process control (SPC) by employing statistics based methodology to monitor and control process controllers 108. For example, SPC can promote efficiency and accuracy of a substrate processing procedure (e.g., by identifying data points that fall within and/or outside control limits).

In some embodiments, a processing chamber can be measured throughout a substrate process procedure. In some embodiments, increased amounts of sensor data are taken during predetermined substrate processing procedures. For example, during or immediately after a wafer is processed, additional sensors can be activated and/or currently activated sensor may take additional data. In some embodiments, process controllers 108 may trigger measurement by metrology tools 114 based on operations to be performed by process tools 104. For example, process controllers 108 can trigger activation of one or more process results (e.g. of metrology tools 114) responsive to a transition period between a first substrate processing procedure and a second substrate processing procedure where a processing chamber is awaiting an upcoming wafer to be processed.

In some embodiments, the extracted features, generated synthetic/engineered data, and statistical analysis can be used in association with machine learning system 170 (e.g., to train, validate, and/or test machine learning model 190). Additionally and/or alternatively, data preparation tool 116 can output data to server 120 to be used by any of critical dimension prediction tool 124 and/or thickness prediction tool 126.

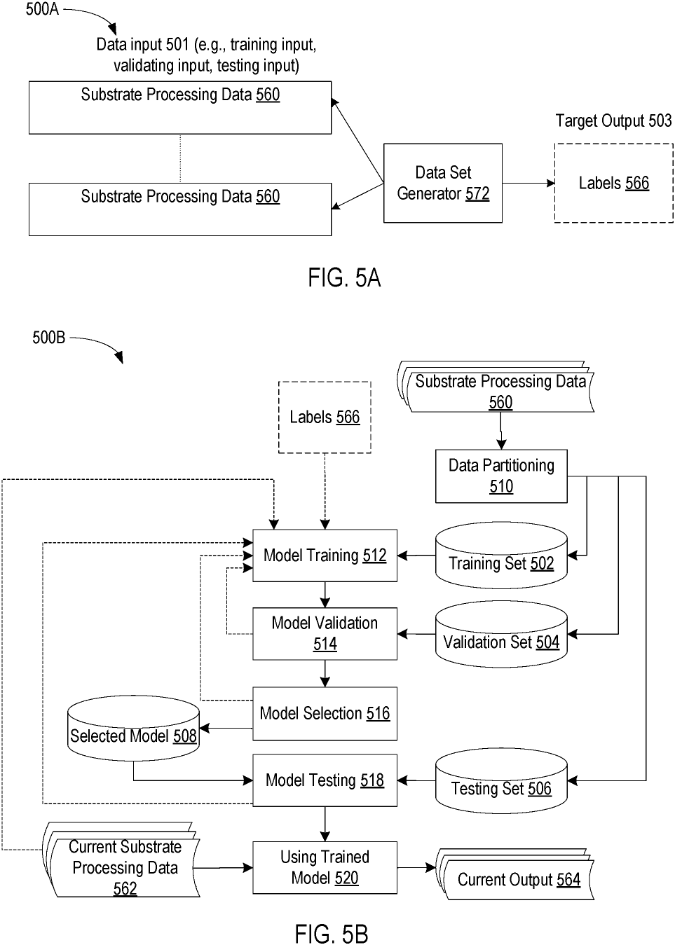

Data store 140 may be a memory (e.g., random access memory), a drive (e.g., a hard drive, a flash drive), a database system, cloud-based system, or another type of component or device capable of storing data. Data store 140 may store one or more historical data 142 including historical sensor data 144, historical process tool data 146 and/or historical process result data 148 of prior chamber conditions, process results and process results of substrates processed in the associated chamber conditions. In some embodiments, the historical data 142 may be used to train, validate, and/or test a machine learning model 190 of machine learning system 170 (See e.g., FIGS. 5A-B for example methodology).

Server 120 may include one or more computing devices such as a rackmount server, a router computer, a server computer, a personal computer, a mainframe computer, a laptop computer, a tablet computer, a desktop computer, etc. The server 120 can include a critical dimension prediction tool 124, and a thickness prediction tool 126. Server 120 includes a cloud server or a server capable of performing one or more cloud-based functions. For example, one or more of operations of critical dimension prediction tool 124 and thickness prediction tool 126 may be provided to a remote device (e.g., client device 120) using a cloud environment.

The critical dimension prediction tool 124 receives chamber process data from manufacturing system 102 and determines process result predictions such as critical dimension prediction of a substrate processed in an environment associated with the chamber sensor data. In some embodiments, the critical dimension prediction tool 124 receives raw sensor data from a chamber monitoring system of manufacturing system 102, in other embodiments, raw sensor data is combined with synthetic data engineered from data preparation tool 116. The critical dimension prediction tool 124 may process sensor data to determine a critical dimension of a substrate processed in association with the processed sensor data. For example, a critical dimension may include a difference between a desired process result parameter and an actual process result parameter (e.g., an etch bias). In some embodiments, the critical dimension prediction tool 124 includes a machine learning model that uses sensor data (e.g., by metrology tools 114), synthetic and/or engineered data (e.g., from data preparation tool 116), general process parameter values corresponding to process procedures 106) and determines critical dimension of substrate processed in an environment associated with the metrology data. In some embodiments, the critical dimension prediction tool receives process tool data (e.g., from metrology system 110). The machine learning model may further use process tool data to predict process result data of a substrate processed with a process tool corresponding to the process tool data. The process tool data may indicate a relative lifetime of a process tool. For example, the process tool data may indicate a number of substrates historically processed by a process tool relative to a process amount or lifetime of other tool in a selection of process tool (e.g., a cluster or grouping of process tools of manufacturing system 102). As will be discussed later, the machine learning model may include a bootstrap aggregation model, a random forest tree decision tree model, and a partial least squares regression (PLS) model, among other models. The machine learning model may include ensemble modeling (e.g., stacked models, boosting models, etc.) comprising multiple models and leveraging higher confidence models for final prediction (e.g., regression) of the received data.

The thickness prediction tool 126 may receive data from metrology tools 114 and/or data preparation tool 116, for example sensor data indicating a state of an environment of a processing chamber, and determine substrate process predictions. For example, the substrate process predictions may include values indicating thicknesses of film of locations across a surface of a substrate. In some embodiments, the thickness prediction tool 126 may use a machine learning model that receives sensor data indicating a state of an environment of a processing chamber from metrology tool 114 and outputs thickness predictions. The thickness predictions may include an average thickness of a film on a first region of a substrate (e.g., a central region) and an average thickness of a film on a second region of the substrate (e.g., an edge region).

As previously described, some embodiments of the critical dimension prediction tool 124 and/or thickness prediction tool 126 may perform their described methodology using a machine learning model. The associated machine learning models may be generated (e.g., trained, validated, and/or tested) using machine learning system 170. The following example description of machine learning system 170 will be described in the context using machine learning system 170 to generate a machine learning model 190 associated critical dimension prediction tool 124. However, it should be noted that this description is purely example. Analogous processing hierarchy and methodology can be used in the generation and execution of machine learning models associated with the critical dimension prediction tool 124 and/or thickness prediction tool 126 individually and/or in combination with each other, as will be discussed further in association with other embodiments.

The machine learning system 170 may include one or more computing devices such as a rackmount server, a router computer, a server computer, a personal computer, a mainframe computer, a laptop computer, a tablet computer, a desktop computer a cloud computer, a cloud server, a system stored on one or more clouds, etc. The machine learning system 170 may include a critical dimension component 194 and a thickness component 196. In some embodiments, the critical dimension component 194 and the thickness component 196 may use historical data 142 to determine critical dimensions and/or thickness predictions of substrates processed by manufacturing system 102. In some embodiments, the critical dimension component 194 may use a trained machine learning model 190 to determine critical dimension predictions based on sensor data and/or process tool data. In some embodiments, the thickness component 196 may use a trained machine learning model to determine thickness predictions based on the sensor data and/or process tool data. The trained machine learning model 190 may use historical data to determine chamber status.

In some embodiments, the machine learning system 170 further includes server machine 172 and server machine 180. The server machine 172 and 180 may be one or more computing devices (such as a rackmount server, a router computer, a server computer, a personal computer, a mainframe computer, a laptop computer, a tablet computer, a desktop computer, a cloud computer, a cloud server, a system stored on one or more clouds, etc.), data stores (e.g., hard disks, memories databases), networks, software components, or hardware components.

Server machine 172 may include a data set generator 174 that is capable of generating data sets (e.g., a set of data inputs and a set of target outputs) to train, validate, or test a machine learning model. The data set generator 174 may partition the historical data 142 into a training set (e.g., sixty percent of the historical data, or any other portion of the historical data), a validating set (e.g., twenty percent of the historical data, or some other portion of the historical data), and a testing set (e.g., twenty percent of the historical data). In some embodiments, the data set generator 174 generates multiple sets of training data. For example, one or more sets of training data may include each of the data sets (e.g., a training set, a validation set, and a testing set).

Server machine 180 includes a training engine 182, a validation engine 184, and a testing engine 186. The training engine 182 may be capable of training a machine learning model 190 using one or more historical sensor data 144 historical process tool data 146, and/or historical process result data 148 of the historical data 142 (of the data store 140). In some embodiments, the machine learning model 190 may be trained using one or more outputs of the data preparation tool 116, the critical dimension prediction tool 124, the thickness prediction tool, and/or 126. For example, the machine learning model 190 may be a hybrid machine learning model using sensor data and/or mechanistic features such as a feature extraction, mechanistic modeling and/or statistical modeling. The training engine 182 may generate multiple trained machine learning models 190, where each trained machine learning model 190 corresponds to a distinct set of features of each training set.

The validation engine 184 may determine an accuracy of each of the trained machine learning models 190 based on a corresponding set of features of each training set. The validation engine 184 may discard trained machine learning models 190 that have an accuracy that does not meet a threshold accuracy. The testing engine 186 may determine a trained machine learning model 190 that has the highest accuracy of all of the trained machine learning models based on the testing (and, optionally, validation) sets.

In some embodiments, the training data is provided to train the machine learning model 190 such the trained machine learning model may receive a new input having new sensor data indicative of a new state of a new processing chamber. The new output may indicate new process results predictions of a substrate processed by the new process chamber in the new state.

The machine learning model 190 may refer to the model that is created by the training engine 182 using a training set that includes data inputs and corresponding target output (historical results of processing chamber under parameters associated with the target inputs). Patterns in the data sets can be found that map the data input to the target output (e.g. identifying connections between portions of the sensor data and resulting chamber status), and the machine learning model 190 is provided mappings that captures these patterns. The machine learning model 190 may use one or more of logistic regression, syntax analysis, decision tree, or support vector machine (SVM). The machine learning may be composed of a single level of linear of non-linear operations (e.g., SVM) and/or may be a neural network.

Critical dimension component 194 may provide current data (e.g., current sensor data associated with a state of a processing chamber during a substrate processing procedure) as input to trained machine learning model 190 and may run trained machine learning model 190 on the input to obtain one or more outputs including a set of values indicating process result predictions. For example, process results predictions may include values indicating critical dimensions (e.g., etch bias, uniformity conditions, thickness, etc.). Critical dimension component 194 may be capable of identifying confidence data from the output that indicates a level of confidence of the predictions. In one non-limiting example, the level of confidence is a real number between 0 and 1 inclusive, where 0 indicates no confidence of the one or more chamber statuses and 1 represents absolute confidence in the chamber status.

For purpose of illustration, rather than limitation, aspects of the disclosure describe the training of a machine learning model and use of a trained learning model using information pertaining to historical data 142. In other implementations, a heuristic model or rule-based model is used to determine a chamber status.

In some embodiments, the functions of client devices 150, server 120, data store 140, and machine learning system 170 may be provided by a fewer number of machines than shown in FIG. 1. For example, in some embodiments server machines 172 and 180 may be integrated into a single machine, while in some other embodiments server machine 172, 180, and 192 may be integrated into a single machine. In some embodiments, the machine learning system 170 may be fully or partially provided by server 120.

In general, functions described in one embodiment as being performed by client device 150, data store 140, metrology system 110, manufacturing system 102, and machine learning system 170 can also be performed on server 120 in other embodiments, if appropriate. In addition, the functionality attributed to a particular component can be performed by different or multiple components operating together.

In embodiments, a “user” may be represented as a single individual. However, other embodiments of the disclosure encompass a “user” being an entity controlled by multiple users and/or an automated source. For example, a set of individual users federated as a group of administrators may be considered a “user.”

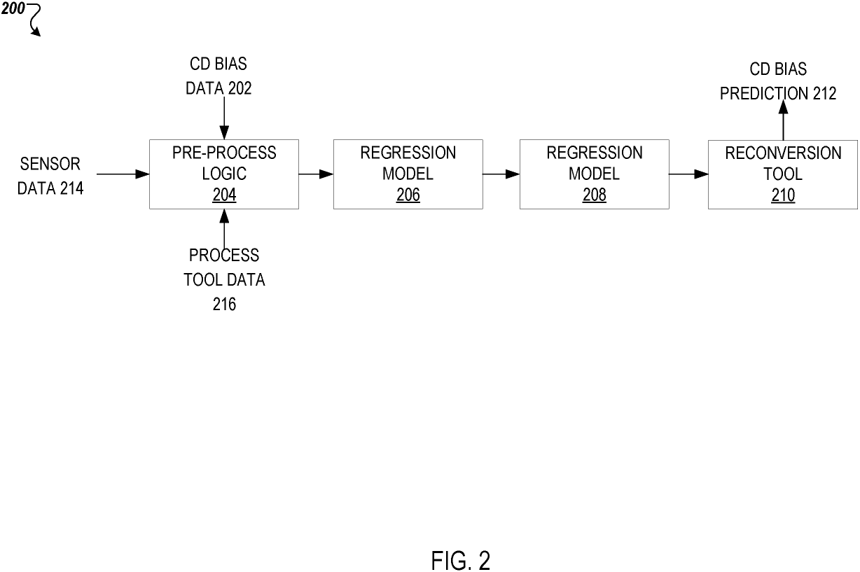

FIG. 2 is a block diagram illustrating a process result prediction system 200 in which implementations of the disclosure may operate. The process result prediction system 200 may include aspects and/or features of system architecture 100.

As shown in FIG. 2, the process result prediction system 200 may include pre-process logic 204. The pre-process logic receives process result data such as in the form of critical dimension (CD) bias data 202 (e.g., etch bias). The process result system may also receive process tool data 216 and sensor data 214. The process result data may indicate a lifetime of a process tool. For example, the lifetime may include values indicating a number of substrates processed by a processing tool (e.g., relative to other tools in a selection of process tools). The sensor may indicate associated states of environments of process chamber process substrates resulting in the CD bias data 202. The pre-process logic 204 may include processing logic operating as a feature extractor. The pre-process logic 204 may reduce a dimensionality of the process result data and the process tool data 216 into groups or features. For example, the pre-process logic 204 may generate features that include one or more tool independent data, time independent data (e.g., data weighted based on the process tool data), sensor data etc. In some embodiments, the pre-process logic 204 performs any of partial least squares (PLS) analysis, principal component analysis (PCA), multifactor dimensionality reduction, nonlinear dimensionality reduction, and/or any combination thereof. In some embodiments, the process logic is designed for edge detection of the process result data and/or process tool data. For example, the processing logic includes methodology that aims at identifying sensor data, process result data and/or process tool data that changes sharply and/or that includes discontinuities (e.g., discontinuities or inconsistencies in the process result data by the same process tool). For example, the pre-process logic 204 may process the first process result data using the first process tool data to generate time-independent process result data.

As shown in FIG. 2, the process result prediction system 200 may include one or more regression models 206, 208. The regression model may be generated and/or trained using the CD bias data 202, the process tool data 216, and/or outputs of pre-process logic 204. Regression models 206 and/or 208 may include a general predictive model.

In some embodiments, regression models 206 and/or 208 may include a general predictive model or function for determining a substrate process result for given chamber conditions (e.g., through sensor data) and process tool data (e.g., relative lifetime of process tools):

$$y = F \left(r\right)$$

In this example, F may represent a function (e.g., a linear function, a non-linear function, a custom algorithm, etc.), y is an process result prediction (CD bias), and r is a vector of features from historical data, r having a length ranging from 1 to n, where n is the total number of features (e.g., may be dynamically determined by pre-process logic 204). The function F may handle a dynamic vector length, so that a process result prediction may be calculated as additional features are determine by pre-process logic 204. Given a sufficient quantity of y and r data, the function F may be modeled to enable the prediction of a y from a given r. The predictive model may be provided by the critical dimension prediction tool 124 of FIG. 1 or by other components.

In some embodiments, one or more of regression model 206 and/or regression model 208 may be modeled using a boosting algorithm. For example, regression models 206, 208 may be represented by predicted function F. Predictive function F may be expressed by an ensemble approach such as gradient boosted regression, where F is expressed by:

$$F \left(r\right) = {\sum }_{b = 1}^{B} \text{λ} {f}^{b} \left(r\right)$$

where λ defines the learning rate. A smaller learning rate requires a higher number of total boosts, B, and therefore more decision trees to be trained. This can increase the accuracy but at a higher cost of training and model evaluation. The sub functions f b are individual decision trees which are fitted to the remaining residual with a tree depth of b. To train this model, the individual models are trained towards the remaining error and these individual error models are then added together to give a final process result prediction. For example, the one or more individual trees may be performed as part of a gradient boosting regression (GBR) algorithm.

In some embodiments, one or more of regression model 206 and/or regression model 208 may be modeled using a Bayesian approach. For example, a Bayesian approach may be leveraged where previous outcomes are used to create naive probabilities of future outcomes, also known as Naive Bayesian techniques. Here, F is defined by:

$$F \left(r \left|Y = y\right)\right) = \frac{P \left(Y = y \left|R = r\right)\right) F \left(r\right)}{P \left(Y = y\right)}$$

where the probability of Y being equal to y based on features x is equal to the historical probabilities being combined using the Bayes Theorem shown above. The function P is simply the historical probability of the input constraint (i.e. Y=y, X=x).

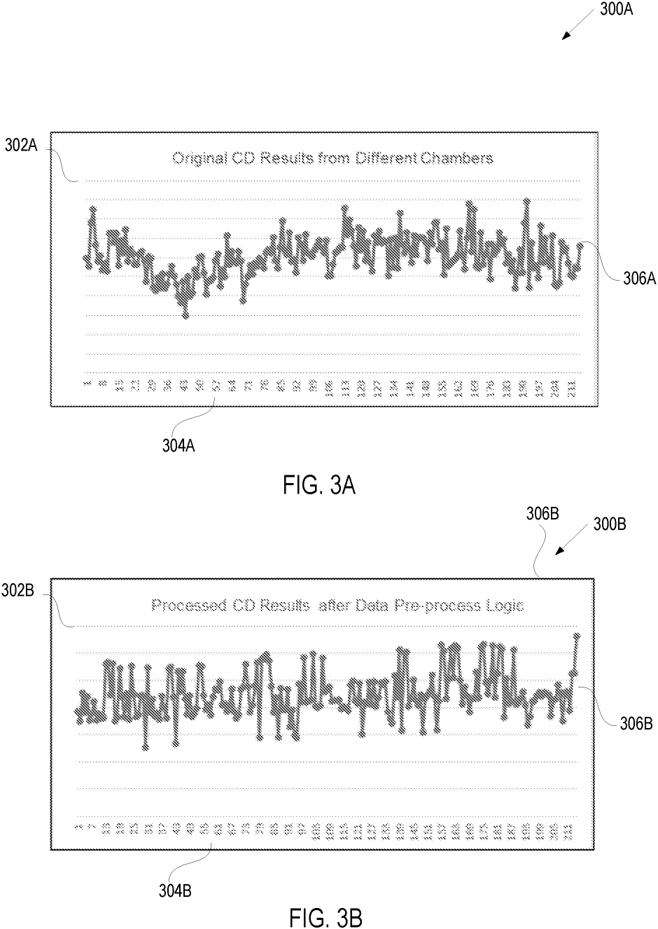

In some embodiments, regression model 206 and/or 208 may be performed on different subsets of data including different outputs of pre-process logic and or outputs of other models. Regression model 206 may be modeled by performing a regression between time-independent CD bias data (output from pre-process logic 204) and sensor data 214. The time-independent CD, as previously described, may include CD bias data 202 processed by weighting the data using the process tool data 216, as is shown in FIGS. 3A-B. Regression model 206 may be generated and/or trained using residuals based on a difference predictions from regression model 206. For example, pre-process logic 204 may outputs processed CD data (e.g., time-independent or process time lifetime accounted for data). Regression model 206 may be trained to receive sensor data and/or process tool data and determine a prediction of the processed CD of an associated substrate. Regression model 208 may receive output from regression model 206 and determine a prediction of a residual CD. The residual CD may be the difference between an actual CD prediction and the output from regression model 206.

Reconversion tool 210 may provide processing logic serving as an aggregator of the one or more regression models 206, 208. For example, outputs from each regression model 206, 208 may be aggregated to determine a final CD bias prediction 212. The reconversion tool may interleave the one or more regression models 206 to operate in parallel or on individual threads to the extent possible (e.g., to the extent the regression model may operate independently one from another).

FIG. 3A depicts a graph 300A illustrating process result data, in accordance with some implementations of the present disclosure. Graph 300A depicts CD results from substrate process in different chamber having different chamber lifetimes (e.g., different historical amounts of process substrates by a process tool and/or process chamber). The graph 300A includes a first axis 304A identifying various individual substrates and a second axis 302A illustrating the CD results of substrates. The data series 306A illustrates the relationship between identified substrate and process result or CD result of an associated substrate. FIG. 3B depicts a graph 300B illustrating process result data after data pre-process logic, in accordance with some implementations of the present disclosure. The data in graph 300A is processed (e.g., using pre-process logic 204 of FIG. 2) to generate processed CD result data. The graph 300B includes similar first axis 304B and second axis 302B. Data series 306B includes the same identified substrate but with processed CD results (data processed to remove time-dependent influences such as process tool lifetime data as previously described).

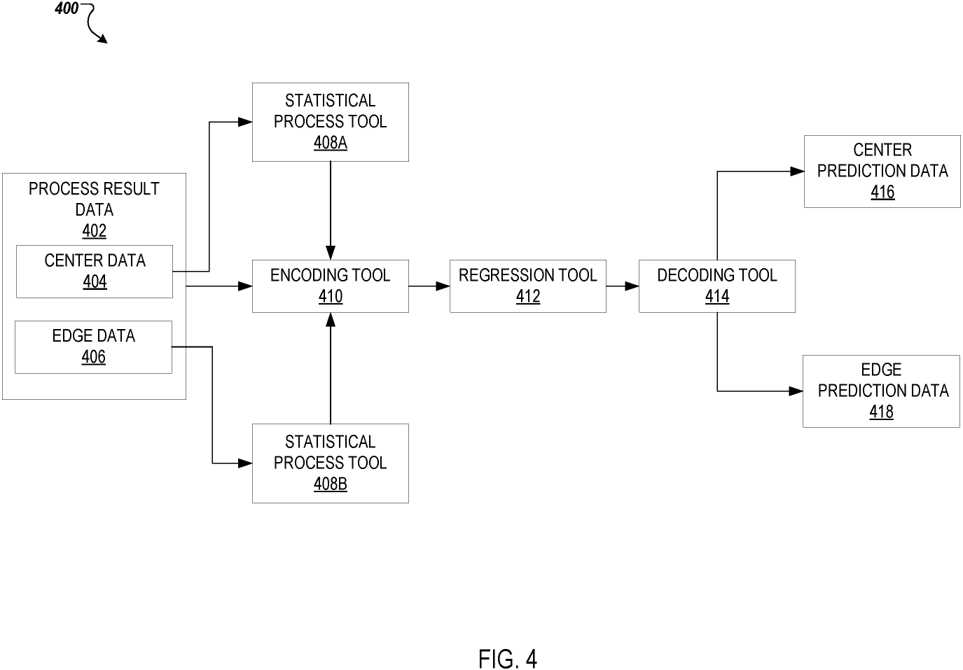

FIG. 4 is a block diagram illustrating a process result prediction system 400 in which implementations of the disclosure may operate. The process result prediction system 400 may receive process result data 402 (e.g., from metrology system 110 and/or data store 140 of FIG. 1). The process result data 402 may include values indicating process results (e.g., CD measurements, thickness measurement of film, etc.). The process result data may include location data or portioned data into regions such as center data 404 and edge data 406 indicating process results measurement associated with various localized regions of a substrate.

As shown in FIG. 4, the process result prediction system 400 may include statistical process tools 408A-B. Statistical process tools 408A-B may be used to process the data based on statistical operations to validate, predict, and/or transform the process result data 402. In some embodiments, the statistical process tools 408A-B include models generated using statistical process control (SPC) analysis to determine control limits for data and identify data as being more or less dependable based on those control limits. In some embodiments, the statistical process tools 408A-B is associated with univariate and/or multivariate data analysis. For example, various parameters can be analyzed using the statistical process tools 408A-B to determine patterns and correlations through statistical processes (e.g., range, minimum, maximum, quartiles, variance, standard deviation, and so on). In another example, relationships between multiple variables can be ascertained using regression analysis, path analysis, factor analysis, multivariate statistical process control (MCSPC) and/or multivariate analysis of variance (MANOVA). In some embodiments, a first statistical process tool 408A is associated with a process result data 402 corresponding to a first localized region of a substrate (e.g., center data 404) and a second statistical process tool 408B is associated with process result data 402 corresponding to a second localized region of a substrate (e.g., edge data 406).

As shown in FIG. 4, the process result prediction system 400 includes an encoding tool 410. The encoding tool 410 may dimensionally reduce the process result data and location data (e.g., center data 404, edge data 406) into groups or features. For example, the encoding tool 410 may generate features that include one or more tool independent data, location dependent process result data, sensor data etc. In some embodiments, the encoding tool performs any of partial least squares (PLS) analysis, principal component analysis (PCA), multifactor dimensionality reduction, nonlinear dimensionality reduction, and/or any combination thereof. In some embodiments, the encoding tool 410 is designed for edge detection of the process result data and/or location data. For example, the encoding tool 410 includes methodology that aims at identifying sensor data, process result data and/or process tool data that changes sharply and/or that includes discontinuities (e.g., discontinuities or inconsistencies in process results across locations of a substrate).

In some embodiments, encoding tool 410 building a model (e.g., a PCA model) to extract correlations for center area/edge area process results and sensor data of process chamber processing substrates resulting in process results corresponding to process results associated with the center area/edge area. In some embodiments, the number of features (e.g., principle components) is dynamic and determined by the encoding tool 410 based on the received process result data 402, sensor data, location data, etc. For the selected number of features (e.g., principle components), a spatial function can be computed with the following:

For the selected number of PC, a spatial function can be computed with following equation:

$$Z = {\sum }_{n = 1}^{N} Y {P}_{n}$$

where Y is the process result data and Pₙ is a spatial conversion of the process result data based on a location the process result data corresponds. For example, the spatial conversion may incorporate location data such as a coordinate representation (e.g., Cartesian coordinate, polar coordinate, etc.) of the associated measured process result. The location corresponding to the associated measurement may be accounted for this PCA procedure to generate a modified of spatially dependent dataset, Z.

As shown in FIG. 4, the process result prediction system 400 may include a regression tool 412. The regression tool 412 builds a prediction model based received encoded data (spatially dependent data). For example, a regression model may be trained with projects (PCs) from encoding tool 410 and can be represented as:

$${\hat{Z}}_{n} = {f}_{n} \left(X\right)$$

In this example, fₙ may represent a function (e.g., a linear function, a non-linear function, a custom algorithm, etc.), Ẑₙ is an spatially dependent PC represented value, and X is a vector of values from historical data (e.g., sensor data), X having a length ranging from 1 to n, where n is the total number of features (e.g., may be dynamically determined by encoding tool 410). The function fₙ may handle a dynamic vector length, so that a process result prediction may be calculated as additional features are determine by encoding tool 410. Given a sufficient quantity of X and Ẑₙ data, the function fₙ may be modeled to enable the prediction of a Ẑₙ from a given X. The predictive model may be provided by the thickness prediction tool 126 of FIG. 1 or by other components.

In some embodiments, one or more models generated and/or trained by regression tool 412 may be modeled using a boosting algorithm (e.g., using gradient boosting regression). For example, regression tool 412 may generate and/or train a model represented by predicted function F. Predictive function F may be expressed by an ensemble approach such as gradient boosted regression, where F is expressed by:

$$F \left(r\right) = {\sum }_{b = 1}^{B} \text{λ} {f}^{b} \left(r\right)$$

where λ defines the learning rate. A smaller learning rate requires a higher number of total boosts, B, and therefore more decision trees to be trained. This can increase the accuracy but at a higher cost of training and model evaluation. The sub functions f b may include models (e.g., individual decision trees) which are fitted to the remaining residual (e.g., with a tree depth of b). To train this model, the individual models are trained towards the remaining error and these individual error models are then added together to give a final process result prediction.

As shown in FIG. 4, the process result prediction system 400 may include a decoding tool that performs decoding methodology associated with (e.g., reverse of, transpose of, inverse of, etc.) methodology performed by encoding tool 410. For example, decoding tool may receive a dimensionality reduced dataset from regression tool 412 and decode the data to generate a dataset indicating process result prediction values. For example, the decoding tool 414 may identify the features leveraged by encoding tool 410 and perform a counter to the dimensionality reduction provided by encoding tool 410. In some embodiments, the decoding tool 414 performs any of partial least squares (PLS) analysis, principal component analysis (PCA), multifactor dimensionality reduction, nonlinear dimensionality reduction, and/or any combination thereof (e.g., in reverse of, transpose of, inverse of, etc. methodology performed by encoding tool 410). For example, an illustrative expression of methodology performed by decoding tool 414 can be

$$\hat{Y} = {\sum }_{n = 1}^{N} {\hat{Z}}_{n} {P}_{n}^{T}$$

where Ŷ is the process result prediction data and

$${P}_{n}^{T}$$

is a reverse spatial conversion (or transposed function) of the process result data based on a location the process result data corresponds. The output from regression tool 412, Ẑₙ, indicating a feature dataset associated with parameter (e.g., principles components (PCs), features) corresponding to encoding methodlogy performed by encoding tool 410.

In some embomdiments, the process result prediction system 400 (e.g., the decoding tool 414) further determines a statistical average of the process results predictions decoded by the decoding tool 414. In some embodiments, the process result prediction system 400 determines a first average thickness associated with a central region of the second substrate and a second average thickness associated with an edge region of the second substrate. For example, methodology for performing the statistical averages may include the following

$${\hat{Y}}_{a v g} = \frac{1}{K} {\sum }_{i = 1}^{K} \hat{Y}$$

where K is number of points in the corresponding region being calculated (e.g., center or edge area). The averages may be output and includes in center prediction data 416 and/or edge prediction data 418.

FIG. 5A is an example data set generator 572 (e.g., data set generator 174 of FIG. 1) to create data sets for a machine learning model (e.g., one or of the MLMs described herein) using substrate processing data 560 (e.g., sensor data 144 and/or process tool data 146 of FIG. 1), according to certain embodiments. System 500A of FIG. 5A shows data set generator 572, data inputs 501, and target output 503.

In some embodiments, data set generator 572 generates a data set (e.g., training set, validating set, testing set) that includes one or more data inputs 501 (e.g., training input, validating input, testing input). In some embodiments, the data set further includes one or more target outputs 503 that correspond to the data inputs 501. The data set may also include mapping data that maps the data inputs 501 to the labels 566 of a target output 503. Data inputs 501 may also be referred to as “features,” “attributes,” or information.” In some embodiments, data set generator 572 may provide the data set to the training engine 182, validating engine 184, and/or testing engine 186, where the data set is used to train, validate, and/or test a machine learning model.

In some embodiments, data set generator 572 generates the data input 501 based on substrate process data 560. In some embodiments, the data set generator 572 generates the labels 566 (e.g., process result measurements such as critical dimension measurement and/or film thickness measurements) associated with the substrate process data 560. In some instances, labels 566 may be manually added to images by users (e.g., inputting measurements). In other instances, labels 566 may be automatically added to input data. In some embodiments, data inputs 501 may include sensor data indicating states of environments of processing chambers and states of processing tools for the substrate process data 560.

In some embodiments, data set generator 572 may generate a first data input corresponding to a first set of features to train, validate, or test a first machine learning model and the data set generator 572 may generate a second data input corresponding to a second set of features to train, validate, or test a second machine learning model.

In some embodiments, the data set generator 572 may discretize one or more of the data inputs 501 or the target outputs 503 (e.g., to use in classification algorithms for regression problems). Discretization of the data input 501 or target output 503 may transform sensor data into instantiable state vectors or feature vectors. In some embodiments, the discrete values for the data input 501 indicate individual sensor parameters (temperature, pressure, vacuum conditions) of a process chamber and/or lifetime data (e.g., number of substrates processed) of a process tool.

Data inputs 501 and target outputs 503 that are being used to train, validate, or test a machine learning model may include information for individual process chamber and/or process tools. For example, the substrate process data 560 and labels 566 may be used to train a system for a particular process tool and/or process chamber.

In some embodiments, the information used to train the machine learning model may be from specific types of processing chambers and/or processing tools having specific characteristics and allow the trained machine learning model to determine substrate process results for a selection of substrates with one or more components sharing characteristics of the specific group (e.g., a common process recipe). In some embodiments, the information used to train the machine learning model may be for data points from two or more process results and may allow the trained machine learning model to determine multiple output data points from the same sensor data (e.g., thickness, critical dimensions, uniformity parameters, etc.). For example, a MLM model inferring a process result may provide thickness prediction for multiple regions and predict and CD bias.

In some embodiments, subsequent to generating a data set and training, validating, or testing machine learning model(s) using the data set, the machine learning model(s) may be further trained, validated, or tested (e.g., with further sensor data, process tool data, process result data, and/or labels) or adjusted (e.g., adjusting weights associated with input data of the machine learning model 190, such as connection weights in a neural network).

FIG. 5B is a block diagram illustrating a system 500B for training a machine learning model to generate outputs 564 (e.g. process result predictions, thickness predictions, critical dimension predictions, process uniformity predictions, etc.), according to certain embodiments. The system 500B may be used to train one or more machine learning models to determine outputs associated with process result data (e.g., critical dimension predictions, thickness predictions, etc.).

At block 510, the system 500B performs data partitioning (e.g., via data set generator 572) of the substrate processing data 560 (e.g., sensor data indicating states of environments of processing chambers, process tool data indicating lifetime data of process tools, and in some embodiments labels 566) to generate the training set 502, validation set 504, and testing set 506. For example, the training set 502 may be 60% of the substrate processing data 560, the validation set 504 may be 20% of the substrate processing data 560, and the testing set 506 may be 20% of the substrate processing data 560. The system 500B may generate a plurality of sets of features for each of the training set 502, the validation set 504, and the testing set 506.

At block 512, the system 500B performs model training using the training set 502. The system 500B may train one or multiple machine learning models using multiple sets of training data items (e.g., each including sets of features) of the training set 502 (e.g., a first set of features of the training set 502, a second set of features of the training set 502, etc.). For example, system 500 may train a machine learning model to generate a first trained machine learning model (e.g., regression model 206) using the first set of features in the training set (e.g., CD bias data 202) and to generate a second trained machine learning model (e.g. regression model 208) using the second set of features in the training set (e.g., process tool data 216). The machine learning model(s) may be trained to output one or more other types of predictions, classifications, decisions, and so on. For example, the machine learning model(s) may be trained to predict process results of substrate processed according to substrate process data 560.

Processing logic determines if a stopping criterion is met. If a stopping criterion has not been met, the training process repeats with additional training data items, and another training data item is input into the machine learning model. If a stopping criterion is met, training of the machine learning model is complete.

In some embodiments, the first trained machine learning model and the second trained machine learning model may be combined to generate a third trained machine learning model (e.g., which may be a better predictor than the first or the second trained machine learning model on its own). In some embodiments, sets of features used in comparing models may overlap (e.g., substrate process from different processing chamber under different processing conditions).

At block 514, the system 500B performs model validation (e.g., via validation engine 184 of FIG. 1) using the validation set 504. The system 500B may validate each of the trained models using a corresponding set of features of the validation set 504. For example, system 500B may validate the first trained machine learning model using the first set of features in the validation set (e.g., feature vectors form a first embedding network) and the second trained machine learning model using the second set of features in the validation set (e.g., feature vectors from a second embedding network).

At block 514, the system 500B may determine an accuracy of each of the one or more trained models (e.g., via model validation) and may determine whether one or more of the trained models has an accuracy that meets a threshold accuracy. Responsive to determining that one or more of the trained models has an accuracy that meets a threshold accuracy, flow continues to block 516.

At block 518, the system 500B performs model testing using the testing set 506 to test the selected model 508. The system 500B may test, using the first set of features in the testing set (e.g., feature vectors from encoding tool 410), the first trained machine learning model to determine the first trained machine learning model meets a threshold accuracy (e.g., based on the first set of features of the testing set 506). Responsive to accuracy of the selected model 508 not meeting the threshold accuracy (e.g., the selected model 508 is overly fit to the training set 502 and/or validation set 504 and is not applicable to other data sets such as the testing set 506), flow continues to block 512 where the system 500 performs model training (e.g., retraining) using further training data items. Responsive to determining that the selected model 508 has an accuracy that meets a threshold accuracy based on the testing set 506, flow continues to block 520. In at least block 512, the model may learn patterns in the substrate process data 560 to make predictions and in block 518, the system 500 may apply the model on the remaining data (e.g., testing set 506) to test the predictions.

At block 520, system 500B uses the trained model (e.g., selected model 508) to receive current data (e.g., current sensor data and process tool data) and receives a current output 564 based on processing of the current substrate processing data 562 by the trained model(s) at block 520. In some embodiments, outputs 564 corresponding to the current substrate processing data 562 are received and the model 508 is re-trained based on the current substrate processing data 562 and the current outputs 564.

In some embodiments, one or more operations of the blocks 510-520 may occur in various orders and/or with other operations not presented and described herein. In some embodiments, one or more operations of blocks 510-520 may not be performed. For example, in some embodiments, one or more of data partitioning of block 510, model validation of block 514, model selection of block 516, or model testing of block 518 may not be performed.

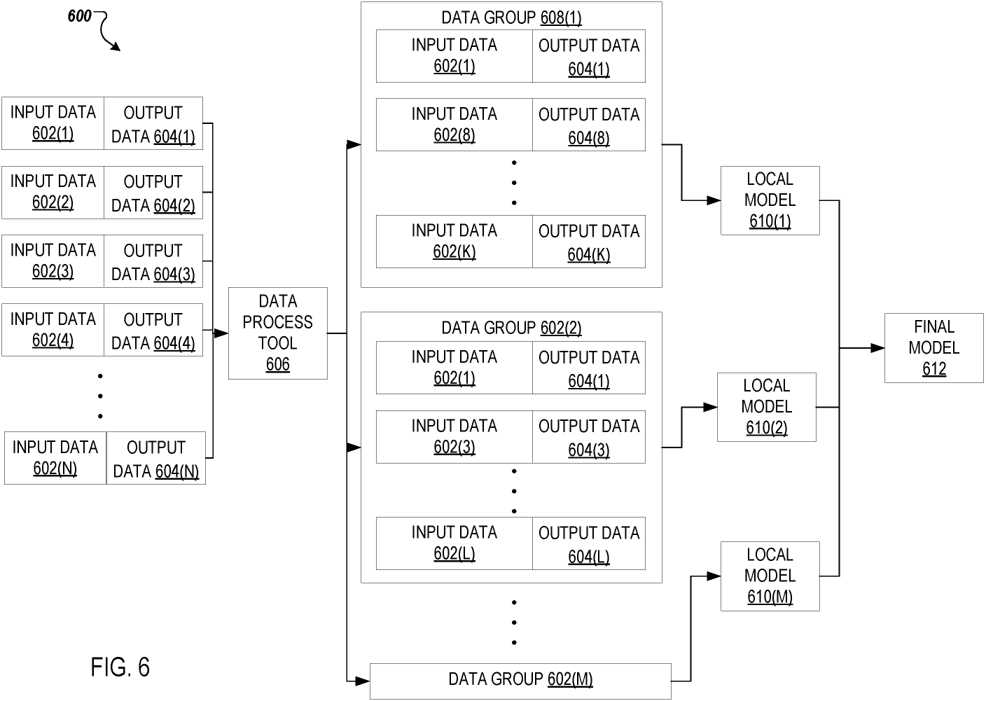

FIG. 6 illustrates block diagram of a process result prediction system 600 using stacked modeling, according to aspects of the disclosure. One or more of the model (e.g., machine learning models) described herein may incorporate model stacking as described in association with FIG. 6. For example, one or more of regression model 206, regression model 208, and/or model generated and/or trained by regression tool 412 may include one or more methodologies and/or process presented in FIG. 6.

As shown in FIG. 6, the process result prediction system 600 may include a dataset including a set of input data 602 and a set of output data 604 corresponding to individual input data 602. The input data 602 and output data 604 may be received by data process tool 606. Data process tool 606 may perform partitioning (e.g., performing methodology described in association with data partitioning in block 510 of FIG. 5) of the input and output data into data groups 608. The data groups 608 may contain different combinations of input data 602 and output data 604 groupings. In some embodiments the data groups 608 are mutually exclusive, however, in other embodiments the data groups 608 include overlapping data points.

As shown in FIG. 6, the process result prediction system generates a stack of local models 610. Each local model may be generated and/or trained based off an individual associated data group 608. Each local model 610 may be trained to generate an independent output from other local models 610 based on the same received input. Each local model may receive new input data and provide new output data based on the trained model. Each model (e.g., due to training dataset differences) may identify different features, artificial parameters, and/or principle components based on the differences in the data groups 604 used to train the corresponding models 610.

The local models 610 may be used in conjunction with one another to generate and/or train a final model. In some embodiments, the final model includes a weighted average ensemble. The weighted average ensemble weights the contribution of each local model 610 by a trust or level of confidence of the contributions (e.g., outputs) received by that corresponding model. In some embodiments, the weights are equivalent across the local models 610 (e.g., each output from each local model 610 is treated equally across the models). In some embodiments, the final model is trained to determine various weights (e.g., contribution weights) of the local models (e.g., using a neural network or deep learning network). For example, one or more types of regression (gradient boosting regression, linear regression, logistical regression, etc.) may be performed to determine one or more contribution weights associated with the local models. The final model 612 may receive as input, outputs from local models 610 as inputs and attempts to learn how to best combine the input predictions to make and improved output prediction.

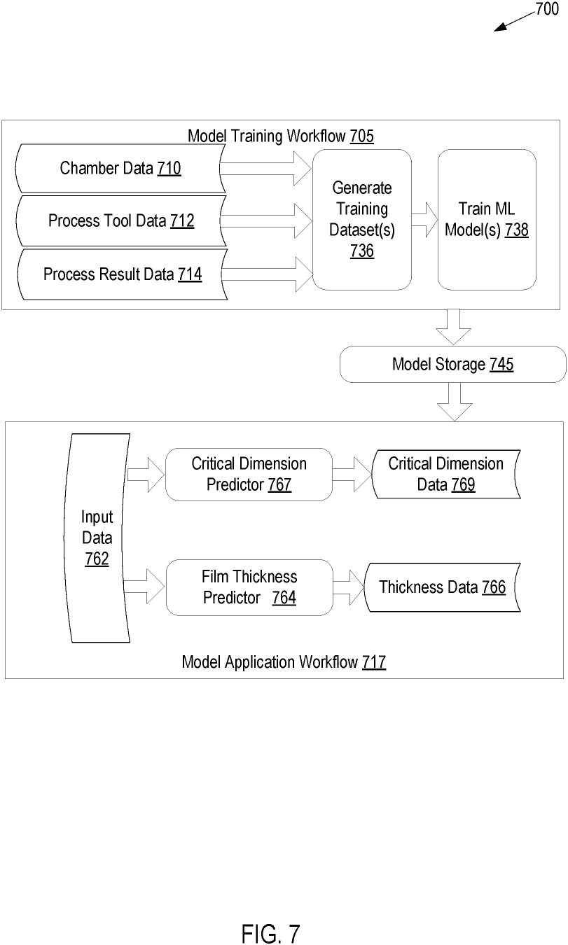

FIG. 7 illustrates a model training workflow 705 and a model application workflow 717 for substrate process result prediction, according to aspects of the disclosure. In embodiments, the model training workflow 705 may be performed at a server which may or may not include a process result prediction application, and the trained models are provided to a process result prediction application, which may perform the model application workflow 717. The model training workflow 705 and the model application workflow 717 may be performed by processing logic executed by a processor of a computing device (e.g., server 120 of FIG. 1). One or more of these workflows 705, 717 may be implemented, for example, by one or more machine learning modules implemented processing device and/or other software and/or firmware executing on a processing device.

The model training workflow 705 is to train one or more machine learning models (e.g., regression models, boosted regression models, principle component analysis models, deep learning models) to perform one or more determining, predicting, modifying, etc. tasks associated with a process result predictor (e.g., critical dimension predictions, film thickness predictions). The model application workflow 717 is to apply the one or more trained machine learning models to perform the determining and/or tuning, etc. tasks for chamber data (e.g., raw sensor data, synthetic data, indicative of a state of a processing chamber). One or more of the machine learning models may receive process result data (e.g., substrate metrology data).

Various machine learning outputs are described herein. Particular numbers and arrangements of machine learning models are described and shown. However, it should be understood that the number and type of machine learning models that are used and the arrangement of such machine learning models can be modified to achieve the same or similar end results. Accordingly, the arrangements of machine learning models that are described and shown are merely examples and should not be construed as limiting

In embodiments, one or more machine learning models are trained to perform one or more of the below tasks. Each task may be performed by a separate machine learning model. Alternatively, a single machine learning model may perform each of the tasks or a subset of the tasks. Additionally, or alternatively, different machine learning models may be trained to perform different combinations of the tasks. In an example, one or a few machine learning models may be trained, where the trained machine learning (ML) model is a single shared neural network that has multiple shared layers and multiple higher level distinct output layers, where each of the output layers outputs a different prediction, classification, identification, etc. The tasks that the one or more trained machine learning models may be trained to perform are as follows:

a. Critical dimension predictor- As discussed previously, various input data such as sensor data, process tool data, pre-processed data, and synthetic data indicative of a state of a processing chamber during a substrate process may be received and processed by critical dimension predictor. The critical dimension predictor may output various values corresponding to various predicted process results of a substrate processed under conditions associated with the input data. For example, the critical dimension predictor may output process result predictions such as critical dimensions predictions (e.g., etch bias values).

b. Film thickness predictor — As discussed previously, various input data such as sensor data, pre-processed data, and synthetic data indicative of a state of a processing chamber during a substrate process may be received and processed by film thickness predictor. The film thickness predictor may output various values corresponding to various predicted process results of a substrate processed under conditions associated with the input data. For example, the film thickness predictor may output process result predictions such as film thickness predictions (e.g., average film thickness of a center region of a substrate, average film thickness of an edge region of a substrate).

For the model training workflow 705, a training dataset containing hundreds, thousands, tens of thousands, hundreds of thousands or more chamber data 710 (e.g., sensor data, synthetic data indicative of states of associated processing chambers) and/or process tool data 712 (e.g., lifetime data including a number of substrates processed by an associate process tool) should be used to form a training dataset. In embodiments, the training dataset may also include an associated process result data 714 (e.g., measured parameters of substrate (e.g., critical dimensions, uniformity requirements, film thickness results, etc.) for forming a training dataset, where each data point may include various labels or classifications of one or more types of useful information. Each case may include, for example, data indicative of a one or more processing chamber processing substrates and associated process results of substrates evaluated during and/or after the substrate processing procedure. This data may be processed to generate one or multiple training datasets 736 for training of one or more machine learning models. The machine learning models may be trained, for example, to automate predicting process result of substrate processed under conditions associated with the chamber data 710 and/or process tool data 712.

In one embodiment, generating one or more training datasets 736 includes performing substrate processing and performing metrology to determine one or more process result measurements (e.g., measured parameters of substrate (e.g., critical dimensions, uniformity requirements, film thickness results, etc.). One or more labels may be used on various iterations of substrate processing and measured process results. The labels that are used may depend on what a particular machine learning model will be trained to do. In some embodiments, as described in other embodiments the chamber data, process results, and/or process tool data may be represented as vectors and the process rates may be represented as one or more matrices.

To effectuate training, processing logic inputs the training dataset(s) 736 into one or more untrained machine learning models. Prior to inputting a first input into a machine learning model, the machine learning model may be initialized. Processing logic trains the untrained machine learning model(s) based on the training dataset(s) to generate one or more trained machine learning models that perform various operations as set forth above.

Training may be performed by inputting one or more of the chamber data 710, process tool data 712 and process result data 714 into the machine learning model one at a time.

After one or more rounds of training, processing logic may determine whether a stopping criterion has been met. A stopping criterion may be a target level of accuracy, a target number of processed images from the training dataset, a target amount of change to parameters over one or more previous data points, a combination thereof and/or other criteria. In one embodiment, the stopping criteria is met when at least a minimum number of data points have been processed and at least a threshold accuracy is achieved. The threshold accuracy may be, for example, 70%, 80% or 90% accuracy. In one embodiment, the stopping criterion is met if accuracy of the machine learning model has stopped improving. If the stopping criterion has not been met, further training is performed. If the stopping criterion has been met, training may be complete. Once the machine learning model is trained, a reserved portion of the training dataset may be used to test the model.

Once one or more trained machine learning models 738 are generated, they may be stored in model storage 745, and may be added to a substrate process rate determination and/or process tuning application. Substrate process rate determination and/or process tuning application may then use the one or more trained ML models 738 as well as additional processing logic to implement an automatic mode, in which user manual input of information is minimized or even eliminated in some instances.

For model application workflow 717, according to one embodiment, input data 762 may be input critical dimension predictor 767, which may include a trained machine learning model. Based on the input data 762, critical dimension predictor 767 outputs information indicating a one or more critical dimension values of a substrate processed under conditions represented by the input data 762. According to one embodiment, input data 762 may be input film thickness predictor 764, which may include a trained machine learning model. Based on the input data 762, film thickness predictor 764 outputs information indicating a one or more film thickness values of a substrate processed under conditions represented by the input data 762.

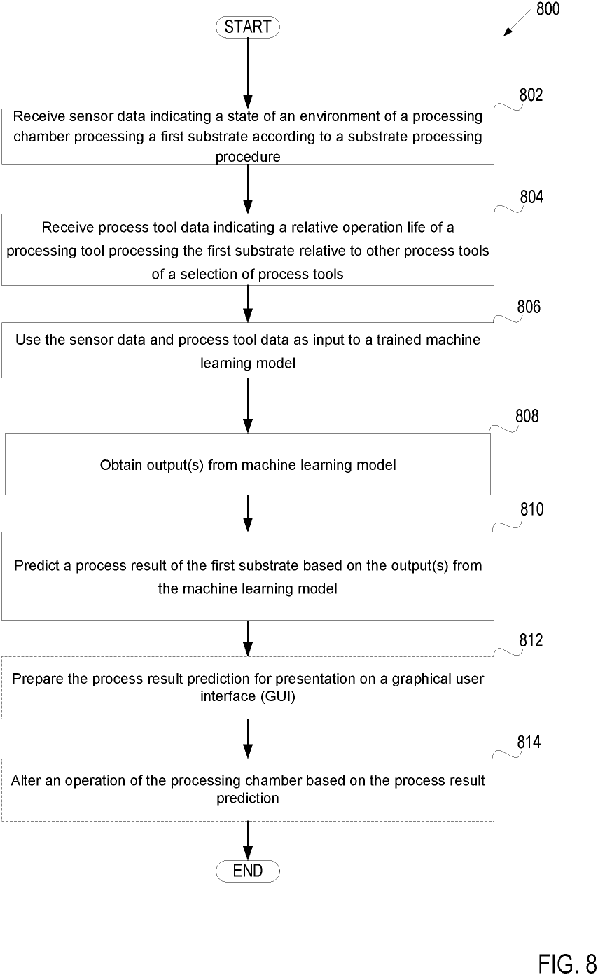

FIG. 8 depicts a flow diagram of one example method 800 for predicting a process results of a substrate process, in accordance with some implementations of the present disclosure. Method 800 is performed by processing logic that may comprise hardware (e.g., circuitry, dedicated logic, etc.), software (such as is run on a general purpose computer system or a dedicated machine) or any combination thereof. In one implementation, the method is performed using server 120 and the trained machine learning model 190 of FIG. 1, while in some other implementations, one or more blocks of FIG. 8 may be performed by one or more other machines not depicted in the figures.

Method 800 may include receiving sensor data (e.g., associated with a processing chamber processing a substrate) and process tool data (e.g., associated with a lifetime of a process tool processing a substrate) and processing the received sensor data and process tool data using a trained machine learning model 190. The trained model may be configured to generate, based on the sensor data and the process tool data, one or more outputs indicating a process result prediction and a level of confidence that the process result prediction accurately represents a process result of a substrate processed under conditions associated with the sensor data and the process tool data.

At block 802, processing logic receives sensor data indicating a state of an environment of a processing chamber processing a first substrate according to a substrate processing procedure. At block 804, processing logic receives process tool data indicating a relative operation life of a processing tool processing the first substrate relative to other process tools of a selection of process tools. For example, the processing tool data may indicate that the process tool has processed a first quantity of substrates since the last preventative maintenance procedure and/or that the process tool has processed a second quantity of substrates more than another process tool or selection of process tools. The state of an environment of a processing chamber is measured during a substrate processing procedure. The sensor data and/or process tool data may be raw data or may be processed using one or more of feature extraction, mechanistic models, and/or statistical model to prepare the sensor for input into a machine learning model. The sensor data may indicate one or more parameters (e.g., temperature, pressure, vacuum conditions, spectroscopy data, etc.) of the processing chamber.

In some embodiments, the sensor data and/or process tool data may further include synthetic data, or data engineered from raw sensor data. For example, as described in previous embodiments, various engineering tools can perform a feature extraction and/or create artificial and/or virtual parameter combinations. A feature extractor (e.g., data preparation tool 116 of FIG. 1) can create various features by performing variable analysis such as process control analysis, univariate limit violation analysis, and/or multivariate limit violation analysis on raw sensor data. In some embodiments, the sensor data is normalized across multiple processing chamber and/or process recipes to create a comparable data set having a common basis. In some embodiments, processing logic processes the sensor data and/or the process tool data to generated modified sensor data. The modified sensor data may include sensor data weighted according the process tool data.

At block 806, processing logic uses the sensor data and the process tool data as input to a trained machine learning model. At block 808, processing logic obtains output(s) from the machine learning model.

At block 810, processing logic predicts a process result of the first substrate based on the output(s) from the machine learning model. In some embodiments, the process result prediction includes a value corresponding to an etch bias of the first substrate. In some embodiments, the prediction of the process result indicates a first average thickness associated with a central region of the first substrate and a second average thickness associated with an edge region of the first substrate.

In some embodiments multiple machine learning models may be employed. For example a first MLM may be used to process the sensor data to obtain a first process result prediction. Processing logic may process the first process result using a second machine learning model to obtain a second process result prediction. Processing logic may further combine the first process result prediction and the second process result prediction to obtain the final process result prediction.

At block 812, processing logic optionally, prepares the process result prediction for presentation on a graphical user interface (GUI). For example, the process result prediction may include a notification associated with the process result prediction such as a process result is beyond a threshold window of acceptable values (e.g., statistical process control (SPC)). The notification may include an action to be performed in associated with a process chamber and/or process tool (e.g., preventative maintenance). In another example, the process result prediction may be displayed on a GUI by displaying alterations to a substrate process (e.g., adjustments to process parameters) to be taken to remedy shortcoming identified by the process result prediction. At block 814, processing logic optionally, alters an operation of the process chamber and/or processing tool based on the process result prediction. For example, processing logic may transmit instructions to one or more process controllers to alter one or more operations of a processing device (e.g., alter a process recipe and/or process parameter, end substrate process of one or more process tools and/or process chambers, initiate preventive maintenance associated with one or more process chambers and/or process tools, etc.)

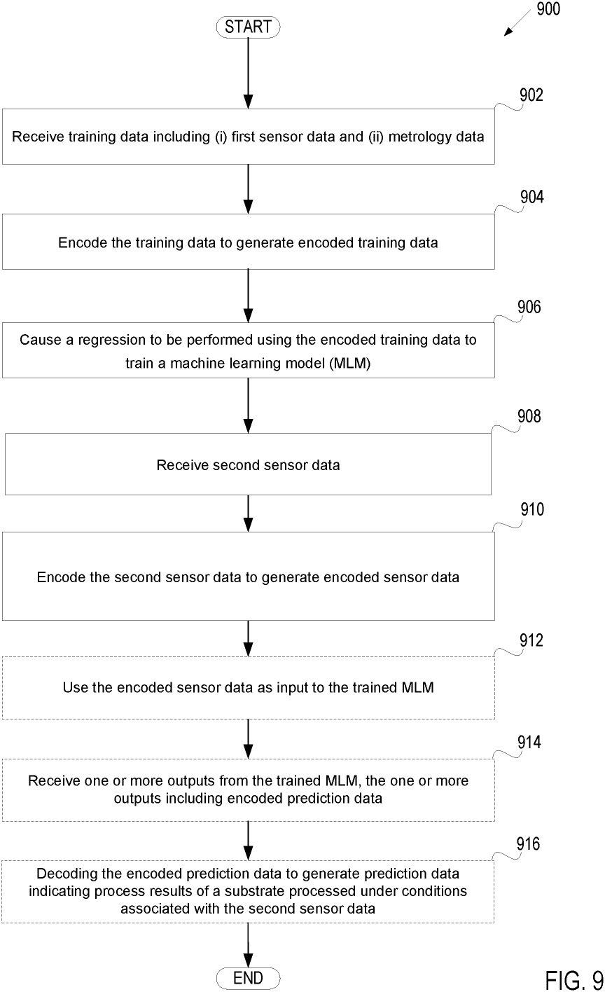

FIG. 9 depicts a flow diagram of one example method 900 for predicting a process results of a substrate process, in accordance with some implementations of the present disclosure. Method 900 is performed by processing logic that may comprise hardware (e.g., circuitry, dedicated logic, etc.), software (such as is run on a general purpose computer system or a dedicated machine) or any combination thereof. In one implementation, the method is performed using server 120 and the trained machine learning model 190 of FIG. 1, while in some other implementations, one or more blocks of FIG. 9 may be performed by one or more other machines not depicted in the figures.

At block 902, processing logic receives training data including (i) first sensor data and (ii) metrology data. The first sensor data indicates a state of an environment of a processing chamber processing a first substrate. The metrology data includes process result data associated with the first substrate processed under conditions associated with the first sensor data. The sensor data and/or metrology tool data may be raw data or may be processed using one or more of mechanistic models and/or statistical model to prepare the sensor for input into a machine learning model. The sensor data may indicate one or more parameters (e.g., temperature, pressure, vacuum conditions, spectroscopy data, etc.) of the processing chamber.

At block 904, processing logic encodes the training data to generate encoded training data. In some embodiments, various engineering tools can perform a feature extraction and/or create artificial and/or virtual parameter combinations. A feature extractor (e.g., data preparation tool 116 of FIG. 1) can create various features by performing variable analysis such as process control analysis, univariate limit violation analysis, and/or multivariate limit violation analysis on raw sensor data. In some embodiments, the sensor data is normalized across multiple processing chamber and/or process recipes to create a comparable data set having a common basis. In some embodiments, processing logic processes the sensor data and/or the process tool data to generated modified sensor data. The modified sensor data may include sensor data weighted according the process tool data. For example, encoding the data can be performed using principal component analysis (PCA).

At block 906, processing logic causes a regression to be performed using the encoded training data to train a machine learning model (MLM). For example, processing logic may generate a regression model with projects (e.g., principle components) generated at block 904. In some embodiments, the regression may be based on a linear function, a non-linear function, a custom algorithm, and the like. In some embodiments, one or more models generated and/or trained by regression tool 412 may be modeled using a boosting algorithm (e.g., using gradient boosting regression). For example, regression tool 412 may generate and/or train a model represented by predicted function F. Predictive function F may be expressed by an ensemble approach such as gradient boosted regression (GBR). The model may be composed of sub functions that include individual decision trees which are fitted to the remaining residual of the prior selection of sub functions. To train this model, the individual models are trained towards the remaining error and these individual error models are then added together to give a final process result prediction.

At block 908, processing logic receives second sensor data. The second sensor data may indicate a state of an environment of a second process chamber processing a second substrate. At block 910, processing logic encodes the second sensor data to generate encoded sensor data. Process logic may leverage the one or more features and/or aspects of data encoding performed at block 904

At block 912, processing logic uses the encoded sensor data as input to the trained MLM. At block 914, processing logic receives one or more outputs from the trained MLM. The one or more outputs include encoded prediction data. At block 916, processing logic decodes the encoded prediction data to generate prediction data indicating process results of a substrate processed under conditions associated with the second sensor data. Processing logic may perform methodology associated with (e.g., reverse of, transpose of, inverse of, etc.) methodology performed to encode the data at blocks 904 and/or 912. For example, processing logic may receive a dimensionality reduced dataset from the trained MLM and then decode the data to generate a dataset indicating process result prediction values. For example, processing logic may identify the features leveraged to encode the data at block 904 and/or 910 and perform a counter to the corresponding dimensionality reduction. In some embodiments, processing logic performs any of partial least squares (PLS) analysis, principal component analysis (PCA), multifactor dimensionality reduction, nonlinear dimensionality reduction, and/or any combination thereof (e.g., in reverse of, transpose of, inverse of, etc. methodology performed at blocks 904 and/or 912).

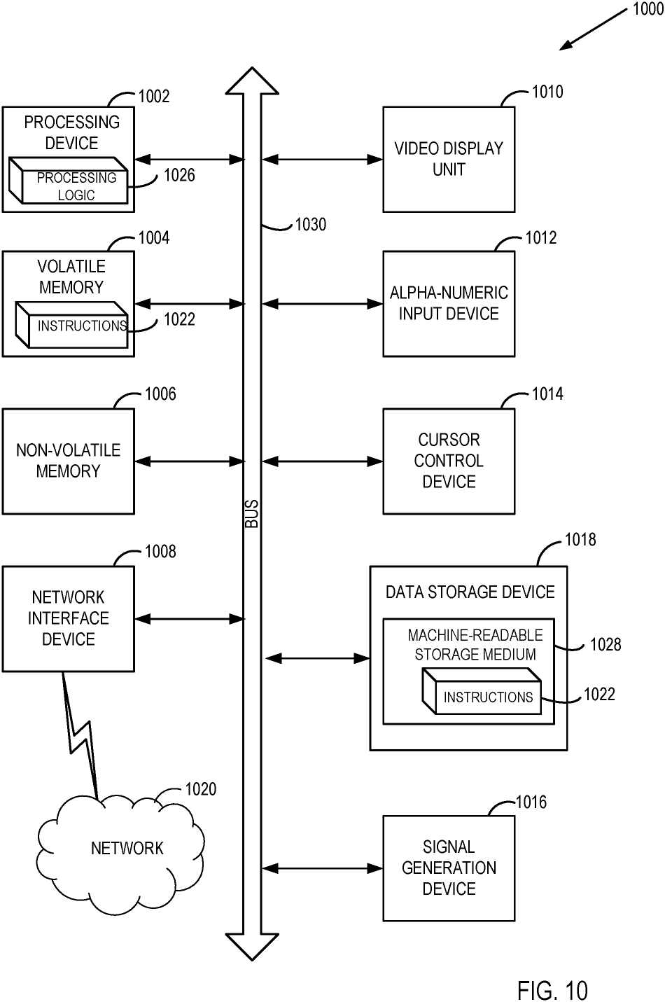

FIG. 10 depicts a block diagram of an example computing device 1000, operating in accordance with one or more aspects of the present disclosure. In various illustrative examples, various components of the computing device 1000 may represent various components of the client devices 150, metrology system 110, server, 120, data store 140, and machine learning system 170, illustrated in FIG. 1.

Example computing device 1000 may be connected to other computer devices in a LAN, an intranet, an extranet, and/or the Internet. Computing device 1000 may operate in the capacity of a server in a client-server network environment. Computing device 1000 may be a personal computer (PC), a set-top box (STB), a server, a network router, switch or bridge, or any device capable of executing a set of instructions (sequential or otherwise) that specify actions to be taken by that device. Further, while only a single example computing device is illustrated, the term “computer” shall also be taken to include any collection of computers that individually or jointly execute a set (or multiple sets) of instructions to perform any one or more of the methods discussed herein.

Example computing device 1000 may include a processing device 1002 (also referred to as a processor or CPU), a main memory 1004 (e.g., read-only memory (ROM), flash memory, dynamic random access memory (DRAM) such as synchronous DRAM (SDRAM), etc.), a static memory 1006 (e.g., flash memory, static random access memory (SRAM), etc.), and a secondary memory (e.g., a data storage device 1018), which may communicate with each other via a bus 1030.

Processing device 1002 represents one or more general-purpose processing devices such as a microprocessor, central processing unit, or the like. More particularly, processing device 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1002 may be configured to execute instructions implementing methods 500A-B, 800-900 illustrated in FIGS. 5, 8-9.

Example computing device 1000 may further comprise a network interface device 1008, which may be communicatively coupled to a network 1020. Example computing device 1000 may further comprise a video display 1010 (e.g., a liquid crystal display (LCD), a touch screen, or a cathode ray tube (CRT)), an alphanumeric input device 1012 (e.g., a keyboard), a cursor control device 1014 (e.g., a mouse), and an acoustic signal generation device 1016 (e.g., a speaker).

Data storage device 1018 may include a machine-readable storage medium (or, more specifically, a non-transitory machine-readable storage medium) 1028 on which is stored one or more sets of executable instructions 1022. In accordance with one or more aspects of the present disclosure, executable instructions 1022 may comprise executable instructions associated with executing methods 500A-B, 800-900 illustrated in FIGS. 5, 8-9.

Executable instructions 1022 may also reside, completely or at least partially, within main memory 1004 and/or within processing device 1002 during execution thereof by example computing device 1000, main memory 1004 and processing device 1002 also constituting computer-readable storage media. Executable instructions 1022 may further be transmitted or received over a network via network interface device 1008.

While the computer-readable storage medium 1028 is shown in FIG. 10 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method, comprising:
receiving, by a processing device, training data comprising (i) first sensor data indicating a first state of an environment of a first processing chamber processing a first substrate, (ii) first process tool data indicating a time-dependent state of the first processing tools processing the first substrate, and (iii) first process result data corresponding to the first substrate; and
training, by the processing device, a first model with input data comprising the first sensor data and the first process tool data and target output comprising the process result data, wherein the trained first model is to receive a new input having second sensor data indicating a second state of an environment of a second processing chamber processing a second substrate and second process tool data indicating a second time-dependent state of a second processing tool processing the second substrate to produce a second output based on the new input, the second output indicating a second process result data corresponding to the second substrate.

2. The method of claim 1, wherein training the first model further comprises:
processing the first process result data using the first process tool data to generate time-independent process result data; and
causing a first regression to be performed using the time-independent process result data and the first sensor data.

3. The method of claim 2, wherein training the first model further comprises:
determining a residual between the first process result data and the time-independent process result data; and
causing a second regression to be performed using the residual and the first sensor data.

4. The method of claim 3, wherein at least one of the first regression or the second regression is performed using a partial least squares (PLS) algorithm.

5. The method of claim 3, wherein at least one of the first regression or the second regression is performed as part of a gradient boosting regression (GBR) algorithm.

6. The method of claim 1, wherein training the first model further comprises:
causing a first regression to be performed using a first subset of training data to generate a first regression model;
causing a second regression to be performed using a second subset of training data to generate a second regression model; and
determining a first accuracy of the first regression model is greater than a second accuracy of the second regression model based on a comparison of the first regression model, the second regression model, and the training data.

7. The method of claim 1, wherein the first process result data comprises a value corresponding to an etch bias of the first substrate.

8. The method of claim 1, wherein the first process tool data indicates relative operation life of the first process tool relative to other process tools of a selection of process tools.

9. The method of claim 1, wherein the first process result data indicates a first average thickness associated with a central region of the first substrate and a second average thickness associated with an edge region of the first substrate.

10. A method, comprising:
receiving, by a processing device, (i) sensor data indicating a state of an environment of a processing chamber processing a first substrate according to a substrate processing procedure and (ii) process tool data indicating a relative operation life of a processing tool processing the first substrate relative to other process tools of a selection of process tools;
processing the sensor data and the process tool data using one or more machine-learning models (MLMs) to determine a prediction of a process result measurement of the first substrate; and
performing, by the processing device, at least one of a) preparing the prediction for presentation on a graphical user interface (GUI) or b) altering an operation of at least one of the processing chamber or the processing tool based on the prediction.

11. The method of claim 10, wherein the prediction of the process result measurement comprises a value corresponding to an etch bias of the first substrate.

12. The method of claim 10, wherein the prediction of the process result measurement comprises indicates a first average thickness associated with a central region of the first substrate and a second average thickness associated with an edge region of the first substrate.

13. The method of claim 10, wherein processing the sensor data and the process tool data further comprises processing the sensor data using the process tool data to generate modified sensor data, wherein the modified sensor data comprises sensor data weighted according to the process tool data, wherein the prediction is determined based on the modified sensor data.

14. The method of claim 10, wherein processing the sensor data and the process tool data further comprises:
processing, using a first MLM of the one or more MLMs, the sensor data to obtain a first process result prediction;
processing, using a second MLM of the one or more MLMs, the first process result prediction to obtain a second process result prediction; and
determining the prediction based on a combination of at least the first process result prediction and the second process result prediction.

15. A method, comprising:
training a machine learning model (MLM) comprising:
receiving training data comprising (i) first sensor data indicating a first state of an environment of a first process chamber processing a first substrate and (ii) metrology data comprising process result measurements and location data indicating first locations across a surface of the first substrate corresponding to the process result measurements;
encoding the training data to generate encoded training data; and
causing a regression to be performed using the encoded training data.

16. The method of claim 15, further comprising:
receiving second sensor data indicating a second state of an environment of a second process chamber processing a second substrate;
encoding the second sensor data to generate encoded sensor data;
using the encoded sensor data as input to the trained MLM;
receiving one or more outputs from the trained MLM, the one or more outputs comprising encoded prediction data; and
decoding the encoded prediction data to generate prediction data comprising values indicating process results of the second substrate in second locations across a surface of the second substrate, the second locations corresponding to the first locations of the first substrate.

17. The method of claim 16, wherein at least one of encoding the sensor data or decoding the encoded prediction data is performed using principal component analysis (PCA).

18. The method of claim 16, wherein the predication data indicates a first average thickness associated with a central region of the second substrate and a second average thickness associated with an edge region of the second substrate.

19. The method of claim 15, wherein the process result measurements comprise a value indicating an etch bias of the first substrate.

20. The method of claim 15, wherein the regression is performed as a part of a gradient boosting regression (GBR).
